(19) United States
(12) Patent Application Publication
(10) Pub. No.: US 2013/0214854 A1
(43) Pub. Date: Aug. 22, 2013

(54) SEMICONDUCTOR DEVICE AND METHOD OF DRIVING THE SAME

(71) Applicants: Katsumi Abe, Yokohama-shi (JP); Hideya Kumomi, Tokyo (JP); Ryo Hayashi, Yokohama-shi (JP); Tatsuya Iwasaki, Machida-shi (JP)

(72) Inventors: Katsumi Abe, Yokohama-shi (JP); Hideya Kumomi, Tokyo (JP); Ryo Hayashi, Yokohama-shi (JP); Tatsuya Iwasaki, Machida-shi (JP)

(73) Assignee: CANON KABUSHIKI KAISHA, Tokyo (JP)

(21) Appl. No.: 13/881,266

(22) PCT Filed: Oct. 31, 2011
(86) PCT No.: PCT/JP2011/075528

§ 371 Date: Apr. 24, 2013

(30) Foreign Application Priority Data
Nov. 8, 2010 (JP) 2010-249443

(51) Int. Cl. H01L 29/786; G05F 3/02

(52) U.S. Cl. CPC H01L 29/7869; G05F 3/02
USPC 327/541; 257/43

(57) ABSTRACT

Provided is a semiconductor device, including an electrode, a first insulator, a first semiconductor having a bandgap of 2 eV or greater, a second insulator, and a second semiconductor, which are stacked on one another, and at least further including one or more electrodes in contact with the first semiconductor and two or more electrodes in contact with the second semiconductor.

### TECHNICAL FIELD

The present invention relates to a semiconductor device and a method of driving the same. More specifically, the present invention relates to a semiconductor device capable of reducing the device area, which is required for higher performance, and a method of driving the semiconductor device.

### BACKGROUND ART

In recent years, a liquid crystal display device and other display devices use a substrate that includes a plurality of thin-film transistors (TFTs) each using amorphous silicon or polysilicon as a channel. In the substrate, the TFTs are used not only as switches but also as components of functional circuits such as a logic circuit, a scanning circuit, and an analog circuit. The scanning circuit of the liquid crystal display device, for example, can be configured by using the TFTs on the same substrate. The use of the TFTs eliminates the need of a crystal silicon IC for the scanning circuit, which has heretofore been connected to pixel wiring from outside the substrate, thus reducing cost of the liquid crystal display device and enhancing ruggedness thereof.

However, the design rule for ordinary TFT manufacturing process is as large as about several μm, which requires a larger area to constitute the functional circuit than when a crystal silicon IC is used. Area constraint reduces the number of TFTs that can be mounted on a circuit and also limits the function and performance of the circuit. As the circuit has a larger area, wiring load increases more and power consumption increases accordingly.

A conceivable method of reducing the area of a circuit is to apply the device stacking technology, called stacked SRAM, disclosed in Non Patent Literature 1. Specifically, it is conceivable to stack a top gate n-type TFT and a bottom gate p-type TFT and provide a common gate electrode between the two TFTs.

Meanwhile, Non Patent Literature 2 discloses the technology for realizing a bipolar transistor by stacking a p-type organic semiconductor and an n-type semiconductor to use the semiconductors as a channel.

### CITATION LIST

### Non Patent Literature

NPL 1: Shichijo et al., Digest of IEDM '84, p. 228
NPL 2: Kuwahara et al., Applied Physics Letters, p. 4765, vol. 85, 2004

### SUMMARY OF INVENTION

### Technical Problem

The technology of Non Patent Literature 1 can reduce the area of an inverter in almost half, but is difficult to apply to other functional circuits than the inverter because of the common gate electrode.

The technology of Non Patent Literature 2 can omit some process steps because there is no need to discriminate a semiconductor between the p-type TFT and the n-type TFT for film formation and patterning, but is difficult to realize the reduction in device area.

It is therefore an object of the present invention to provide a semiconductor device that includes a field-effect transistor (FET) having a novel structure so that a functional circuit may be configured with a smaller area than a conventional one, and also provide a method of driving the semiconductor device. That is, it is an object of the present invention to reduce the mounting area of a functional circuit constituted by an FET.

### Solution to Problem

In order to solve the above-mentioned problems, the present invention provides a semiconductor device, including an electrode, a first insulator, a first semiconductor having a bandgap of 2 eV or greater, a second insulator, and a second semiconductor, which are stacked on one another, in which: the electrode is in contact with the first insulator; the first semiconductor is sandwiched between the first insulator and the second insulator; the second semiconductor is in contact with the second insulator; and the semiconductor device at least further includes one or more electrodes in contact with the first semiconductor and two or more electrodes in contact with the second semiconductor.

Further, the present invention provides a method of driving a semiconductor device including an electrode, a first insulator, a first semiconductor having a bandgap of 2 eV or greater, a second insulator, and a second semiconductor, which are stacked on one another, the electrode being in contact with the first insulator, the first semiconductor being sandwiched between the first insulator and the second insulator, the second semiconductor being in contact with the second insulator, the semiconductor device at least further including one or more electrodes in contact with the first semiconductor and two or more electrodes in contact with the second semiconductor, including applying a voltage to a first electrode, which is the electrode in contact with the first insulator, and a voltage to a second electrode, which is the one or more electrodes in contact with the first semiconductor, to thereby change a resistance of a channel region of the second semiconductor.

### Advantageous Effects of Invention

According to the present invention, at least part of the functional circuits, including a logic circuit, can be configured with almost half the area of a conventional one. Therefore, the area of the semiconductor device can be reduced to cut down device cost and power consumption.

Further features of the present invention will become apparent from the following description of exemplary embodiments with reference to the attached drawings.

### BRIEF DESCRIPTION OF DRAWINGS

FIG. 1 is a view illustrating an a-IGZO TFT.

FIG. 2 is a graph showing transfer characteristics and internal electrode voltages of the a-IGZO TFT of FIG. 1.

FIG. 3 is a cross-sectional view of a variable channel resistance circuit according to Example 1.

FIG. 4 is a circuit diagram of a conventional variable channel resistance circuit.

FIG. 5 is a cross-sectional view of a NAND circuit according to Example 2.

FIG. 6 is a circuit diagram of a conventional NAND circuit.

FIG. 7 is a cross-sectional view of a NOR circuit according to the present invention.

FIG. 8 is a circuit diagram of a conventional NOR circuit.

FIG. 9 is a cross-sectional view of a binary buffer circuit according to Example 4.

FIG. 10 is a circuit diagram of a conventional binary buffer circuit.

FIG. 11 is a cross-sectional view of a NAND circuit according to Example 3.

FIG. 12 is a plan view of the NAND circuit according to Example 3.

### DESCRIPTION OF EMBODIMENTS

Preferred embodiments of the present invention will now be described in detail in accordance with the accompanying drawings.

A semiconductor device according to the present invention has the structure in which an electrode, a first insulator, a first semiconductor having a bandgap of 2 eV or greater, a second insulator, and a second semiconductor are stacked on one another. The electrode is in contact with the first insulator, the first semiconductor is sandwiched between the first insulator and the second insulator, and the second semiconductor is in contact with the second insulator. The semiconductor device further at least includes one or more electrodes in contact with the first semiconductor and two or more electrodes in contact with the second semiconductor. Hereinafter, the electrode in contact with the first insulator is referred to as “first electrode”, and the electrode in contact with the first semiconductor is referred to as “second electrode”.

The semiconductor device and a method of driving the same according to the present invention utilize a phenomenon that the field effect generated by voltages applied to the first electrode and the second electrode can put the first semiconductor substantially into a conductive state or an insulating state. As used herein, the term “substantially” refers to such a state that is regarded as the conductive state or the insulating state in terms of electrical characteristics when the semiconductor device is driven. The insulating state means that, when the stack of the first insulator and the first semiconductor in the insulating state is sandwiched by the electrodes, the law of conservation of charge is satisfied between the electrodes. In other words, the insulating state is physically a fully depleted state that forms no inversion layer. As used herein, the above-mentioned “fully depleted state that forms no inversion layer” includes not only a fully depleted state but also such a state that may be regarded as comparable to the “fully depleted state that forms no inversion layer” in terms of device characteristics, specifically, a state in which a semiconductor layer is substantially depleted over the film thickness direction by being applied with an electric field. As used herein, the phrase “is substantially depleted” includes not only a fully depleted state but also such a state that is regarded as insulated in terms of electrical characteristics.

When the first semiconductor is in the conductive state, the first semiconductor functions as a gate, the second insulator functions as a gate insulator, and at least part of the second semiconductor serves as a channel whose resistance is controlled by a voltage at the electrode connected to the first semiconductor. When the first semiconductor is in the insulating state, on the other hand, the first electrode functions as a gate, three layers of the first insulator, the first semiconductor, and the second insulator all function as a gate insulator, and at least part of the second semiconductor serves as a channel whose resistance is controlled by a voltage at the first electrode. When the first semiconductor forms an inversion layer, an electric field from the first electrode does not reach the second semiconductor and the resistance of the second semiconductor cannot be controlled.

Assuming the first semiconductor as an n-type semiconductor, the case where the first semiconductor enters the insulating state by the field effect, that is, the case where the first semiconductor is fully depleted is described below.

In order to fully deplete the first semiconductor, a voltage V1 applied to the first electrode and a voltage V2 of the electrode connected to the first semiconductor need to satisfy the following relation:

−(V1−V2−VFB)≧(q·ND1/(2−∈s1))·(ts1²+2·ts1·∈s1/C1) Expression (1)

where q is the elementary charge, VFB is the flat band voltage in the first electrode/first insulator/first semiconductor structure, ND1, ts1, and ∈s1 are the donor density (or carrier density under no application of an electric field), the thickness, and the dielectric constant of the first semiconductor, respectively, and C1 is the capacitance per unit area of the first insulator. From Expression (1), when VFB=0 V, the first semiconductor can be fully depleted if the voltage applied to the first electrode is equal to or lower than a minimum voltage that is applied to the electrode connected to the first semiconductor. The voltage V1 of the first electrode for realizing full depletion can be increased by reducing ND1 and ts1 and increasing ∈s1 and C1. When the VFB is 0 V, the specific dielectric constant of the first semiconductor is 10, the C1 is 3.5×10⁻⁸ (F/cm²) (equivalent to that of SiO₂ with thickness of 100 (nm)), and the ND1 is 10¹⁸ (cm⁻³), 2 (nm) or less of the thickness ts1 is necessary to fully deplete the first semiconductor under the condition of −(V1−V2)=1 (V). It is therefore preferred that the donor density be 10¹⁸ (cm⁻³) or less. Note that, even when the donor density is 10¹⁸ (cm⁻³) or more, the voltage for full depletion can be increased with the use of a high-dielectric constant insulator as the first insulator.

When the voltage applied to the first electrode further decreases, the first semiconductor forms an inversion layer and enters the conductive state. On this occasion, the device of the present invention can no longer realize intended operation. In order to realize stable operation, it is preferred to use a material that can realize a fully depleted state in a wide voltage range for a long period of time. Assuming the first semiconductor as an n-type semiconductor, the case where the first semiconductor forms an inversion layer is described below.

An inversion layer is formed in the first semiconductor by holes that are injected from the electrode connected to the first semiconductor or holes that are formed by electron-hole pair generation in a depletion layer of the first semiconductor. Hole density per unit area necessary for forming the inversion layer is about 1×10¹² (cm⁻²) when the voltage at the first electrode is −5 (V) and the C1 is 3.5×10⁻⁸ (F/cm²). When the film thickness of the first semiconductor is 10 (nm), holes of about 1×10¹⁸ (cm⁻³) are necessary.

Injection of holes can be suppressed by controlling the difference between the valence band of the first semiconductor and the work function of the electrode connected to the first semiconductor. If a region with higher electron density is added/inserted between the electrode and the first semiconductor, electron-hole pair annihilation is promoted and the amount of holes reaching the first semiconductor is reduced.

Electron-hole pair generation, on the other hand, follows the Shockley-Read-Hall (SRH) model. According to the SRH model, the electron-hole pair generation rate U is expressed as follows:

U≦ni·vth·σ·Nt/2 Expression (2)

where ni is the intrinsic carrier density of the first semiconductor, with is the heat speed, σ is the capture cross-section, and Nt is the trap density at the intrinsic Fermi level. Note that, the same capture cross-section σ is assumed for holes and electrons. The intrinsic carrier density has the following relation with the bandgap Eg:

log(ni)=−(Eg/(2·k·T))·log(e)+(½)log(Nc·Nv) Expression (3)

where k is the Boltzmann constant, T is the absolute temperature, e is the base of natural logarithm, Nc is the effective density of states in the conduction band, and Nv is the effective density of states in the valence band. From Expression (3), log(e)/(2·k·T) is about −8.4 (eV⁻¹), which indicates that, when Eg increases by 0.1 (eV), log(ni) decreases by about −1, that is, ni decreases by one order of magnitude.

From Expression (2) and Expression (3), the relation between the bandgap Eg and a minimum time required for inversion layer formation can be estimated. For example, in the case of a typical semiconductor of Si (Eg=1.1 (eV)), when Nc=Nv=3×10¹⁹ (cm⁻³), ni is about 2×10¹⁰ (cm⁻³) from Expression (3). When with is 10⁷ (cm/s), σ is 10⁻¹⁵ (cm⁻²), and Nt is 10¹⁷ (cm⁻³), 9×10¹⁸ (cm⁻³ s⁻¹) is obtained as the electron-hole pair generation rate U from Expression (2). Because the necessary hole density is about 1×10¹⁸ (cm⁻³), preparation of holes in this case requires at least 0.1 (s). In addition, the use of the above-mentioned numerical values obtains the minimum time required for inversion layer formation, that is, about 48 days for the bandgap of 2.0 (eV), about 300 years for the bandgap of 2.4 (eV), and about 100,000 years for the bandgap of 2.7 (eV). It is therefore considered that, as long as the bandgap is equal to or greater than 2.0 (eV), the formation of an inversion layer caused by electron-hole pair generation in ordinary operation can be neglected. The bandgap is more preferably 2.4 (eV) or greater, still more preferably 2.7 (eV) or greater.

By the way, in the case where the TFT included in the semiconductor device of the present invention is a TFT using amorphous In—Ga—Zn—O (a-IGZO) as a channel, the formation of an insulating state can be confirmed by way of experiment. a-IGZO is an amorphous metal-oxide semiconductor, and has a bandgap of about 3 (eV).

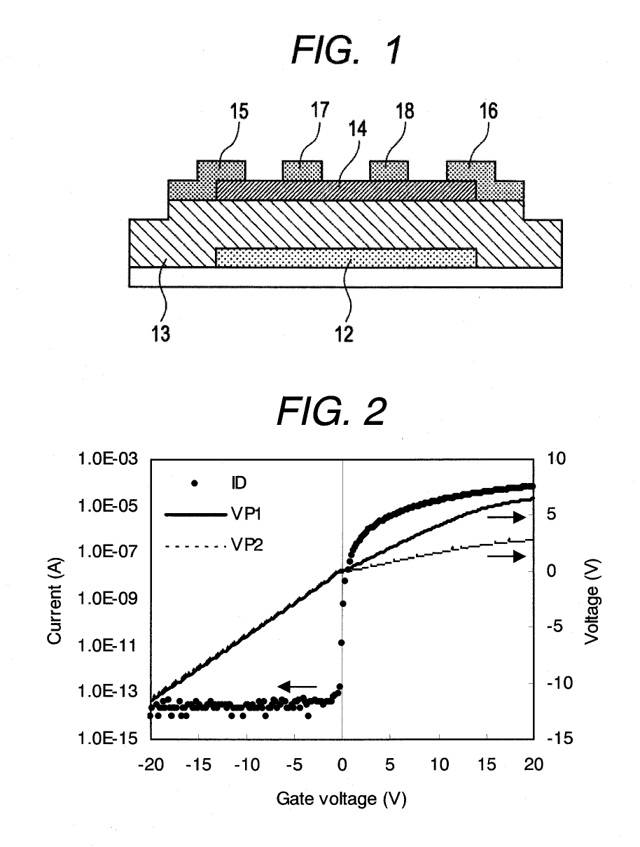

FIG. 1 is a cross-sectional view of the structure of a TFT using a-IGZO as a channel. The TFT of FIG. 1 includes on a substrate a gate 12, a gate insulator 13, a semiconductor 14, a drain 15, a source 16, a first inner electrode 17, and a second inner electrode 18. The TFT includes the first inner electrode 17 and the second inner electrode 18 between the source 16 and the drain 15, and is called gated-four-probe TFT. Voltages of the first inner electrode 17 and the second inner electrode 18 are represented by VP1 and VP2, respectively. FIG. 2 shows a value of a drain current flowing when a gate voltage is changed from 20 (V) to −20(V) with a source voltage of 0 (V) and a drain voltage of 0.1 (V) or 12 (V). FIG. 2 superimposes the voltages VP1 and VP2. When the gate voltage is 0 (V) or higher, a drain current flows and the voltages VP1 and VP2 indicate an intermediate value obtained by equally dividing the source voltage and the drain voltage. When the gate voltage is equal to or lower than 0 (V), on the other hand, the voltages VP1 and VP2 each decrease as the gate voltage decreases, and exhibit a negative voltage. This demonstrates that, following the law of conservation of charge, the voltages of the internal electrodes each decrease as the gate voltage decreases, so that a-IGZO enters the insulating state.

The above description assumes the first semiconductor as an n-type semiconductor, but the same approach can be taken in a p-type semiconductor. In this case, some descriptions are modified. For example, the donor density in Expression (1) is replaced with acceptor density. When VFB=0 V, the first semiconductor can be fully depleted if the voltage applied to the first electrode is equal to or higher than a maximum voltage that is applied to the electrode connected to the first semiconductor. Injection of electrons for forming an inversion layer can be suppressed by controlling the difference between the conduction band of the first semiconductor and the work function of the electrode connected to the first semiconductor. In addition, if a region with higher hole density is added/inserted between the electrode and the first semiconductor, electron-hole pair annihilation is promoted and the amount of electrons reaching the first semiconductor is reduced.

Next, the materials of the respective members included in the semiconductor device of the present invention are described.

As the material of the first semiconductor, a wide gap metal-oxide semiconductor including a-IGZO is suitable. As the n-type semiconductor, In—Ga—Zn—O, In—Zn—O, In—Sn—O (ITO), In—O, Zn—O, Ga—O, Sn—O (Sn₂O), or the like may be used. Those materials each have a high Eg and a low hole mobility as well. The material having a low hole mobility is more preferred because formation of an inversion layer due to injection may be suppressed. As the p-type semiconductor, Zn—Rh—O, Cu—O, Sr—Cu—O, Ni—O, La—Cu—O—(S, Se, Te), Cu—Al—O, Sn—O (SnO), or the like may be used. A wide gap semiconductor other than oxide may also be used. In this case, examples of the wide gap semiconductor include Zn—Se, Zn—S, Cd—Te, Ga—N, Si—C, and C (diamond). Those semiconductors may each have any of crystalline, polycrystalline, microcrystalline, and amorphous structures.

The material of the second semiconductor is not particularly limited as long as the material is a semiconductor usable as a channel of a field-effect transistor. Examples of the semiconductor include not only a wide gap semiconductor but also a Si-based semiconductor such as crystal Si, polycrystalline Si, microcrystalline Si, and amorphous Si, and an organic semiconductor.

The materials of the first insulator and the second insulator can use an insulator material that is used in a conventional field-effect transistor.

Hereinafter, exemplary embodiments of the semiconductor device and the method of driving the same according to the present invention are described.

### First Embodiment

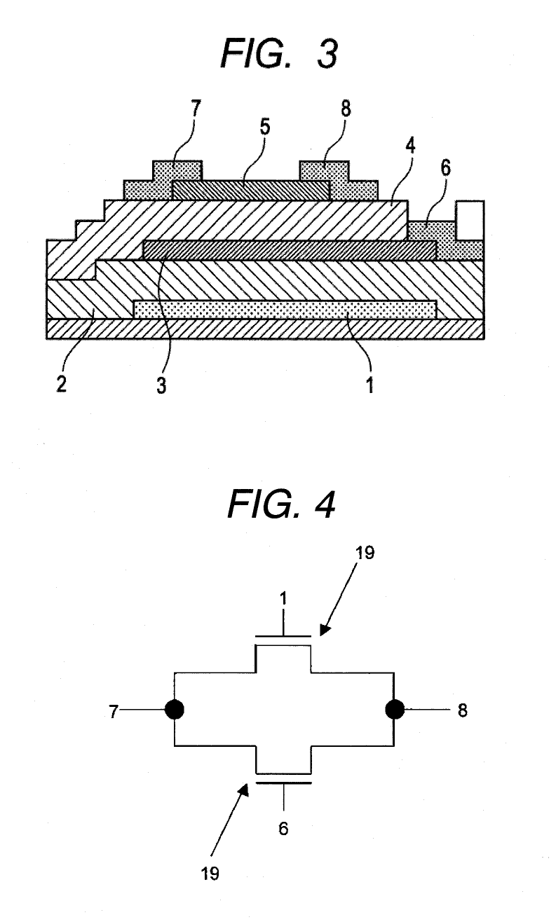

A first embodiment of the present invention is an example in which the semiconductor device of the present invention is used for a variable channel resistance circuit. FIG. 3 is a cross-sectional view of the variable channel resistance circuit of the first embodiment.

The variable channel resistance circuit of the first embodiment has the structure in which a first electrode 1, a first insulator 2, a first semiconductor 3 which is an n-type semiconductor having a bandgap of 2 eV or greater, a second insulator 4, and a second semiconductor 5 which is an n-type semiconductor, are stacked on a substrate. The variable channel resistance circuit further includes a second electrode 6 that is connected to the first semiconductor 3, and a third electrode 7 and a fourth electrode 8 that are connected to the second semiconductor 5. The n-type first semiconductor 3 is fully depleted to enter an insulating state when a voltage applied to the first electrode 1 is equal to or lower than a voltage applied to the second electrode 6. When the voltage applied to the first electrode 1 is equal to or higher than the voltage applied to the second electrode 6, on the other hand, the n-type first semiconductor 3 enters an accumulation state. The full depletion of the n-type first semiconductor 3 is realized by setting a minimum value in the range of the voltage applied to the first electrode 1 to be equal to or smaller than a minimum value in the range of the voltage applied to the second electrode 6. The effect of the present invention is obtained also by setting a minimum value of the voltage applied to the second electrode 6 to be equal to or larger than a maximum value of the voltages applied to the plurality of electrodes that are connected to the second semiconductor 5. In the first embodiment, the maximum value and the minimum value of each of the voltages applied to the first electrode 1 and the second electrode 6 are represented by V1 and V2, respectively, the voltage applied to the third electrode 7 is represented by VD, and the voltage applied to the fourth electrode 8 is represented by VS. VD is higher than VS, and V2 is higher than VD. Through the application of the voltages to the first electrode 1 and the second electrode 6, the resistance of a channel region of the second semiconductor 5 is changed. To be exact, the resistance of the channel region of the second semiconductor 5 is changed by the field effect generated from the first electrode 1 applied with the voltage or by the field effect generated from the first semiconductor 3 due to a change in electrical characteristics of the first semiconductor caused by the voltage applied to the second electrode 6. In this way, the resistance of the channel region of the second semiconductor 5 can be controlled to a desired value. Note that, the “field effect generated from the first electrode 1” means that the first electrode 1 is a starting point of the field effect (reference point for determining the potential difference (for determining the magnitude of the field effect) with the point as a reference).

As the first semiconductor 3, it is preferred to use a metal-oxide semiconductor and more preferred to use a metal-oxide semiconductor containing In, Ga, and Zn as main constituent elements.

(1) When both the voltages at the first electrode 1 and the second electrode 6 are V1, the first semiconductor 3 is fully depleted and enters an insulating state. On this occasion, in a transistor that uses the second semiconductor 5 as a channel, the first electrode 1 functions as a gate, and a stacked film of three layers of the first insulator 2, the first semiconductor 3, and the second insulator 4 functions as a gate insulator. When capacitances per unit area of the first insulator 2, the first semiconductor 3, and the second insulator 4 are represented by C1, CS1, and C2, respectively, a capacitance C per unit area as the stacked gate insulator is expressed as follows.

C=(C1·CS1·C2)/(CS1·C2+C1·C2+C1·CS1) Expression (4)

A current ID flowing between the third electrode 7 and the fourth electrode 8 is expressed as follows when VD−VS is small:

ID=μ·(W/L)·C·(V1−VS−VTH2)·(VD—VS) Expression (5)

where μ is the mobility of the second semiconductor 5, W and L are the channel width and the channel length of the transistor using the second semiconductor 5 as a channel, and VTH2 is the threshold voltage of the transistor. A resistance RCH of a channel region of the second semiconductor 5 in this case is expressed as follows.

RCH=(VD−VS)/ID=1/(μ−(W/L)·C·(V1−VS−VTH2)) Expression (6a)

(2) When both the voltages at the first electrode 1 and the second electrode 6 are V2, the first semiconductor 3 is fully depleted and enters the insulating state. The resistance RCH of the channel region of the second semiconductor 5 in this case is expressed as follows.

RCH=1/(μ−(W/L)·C·(V2−VS−VTH2)) Expression (6b)

(3) When the voltage at the first electrode 1 is V2 and the voltage at the second electrode 6 is V1, the first semiconductor 3 is fully depleted and enters the insulating state. The resistance RCH of the channel region of the second semiconductor 5 in this case is expressed by Expression (6b).

(4) When the voltage at the first electrode 1 is V1 and the voltage at the second electrode 6 is V2, the voltage of the first semiconductor 3 is V2. On this occasion, in the transistor that uses the second semiconductor 5 as a channel, the first semiconductor 3 functions as a gate and the second insulator 4 functions as a gate insulator. The resistance RCH of the channel region of the second semiconductor 5 in this case is expressed as follows.

RCH=1/(μ·(W/L)·C2·(V2−VS−VTH2)) Expression (6c)

As described above, depending on the voltages at the first electrode 1 and the second electrode 6, the channel resistance of the second semiconductor 5 can be changed to three different values. Realizing this function by a commonly-used transistor requires two transistors that are disposed in parallel as illustrated in the circuit diagram of FIG. 4. On the other hand, the area required for the variable channel resistance circuit of the first embodiment is the one corresponding to one transistor. The variable channel resistance circuit of the first embodiment can therefore be reduced in circuit area in almost half as compared to a conventional one.

The back gate effect, which should be taken into account when semiconductors are stacked as in the present invention, is now described. It is known that a transistor in which a gate electrode, a gate insulator, a channel semiconductor, a back gate insulator, and a back gate electrode are stacked is changed in threshold voltage when the back gate electrode is applied with a voltage. The relation between a back gate voltage VB and a threshold voltage VTH is approximately expressed as follows:

VTH=VTH0−(CG2/CG1)·VB Expression (7)

where VTH0 is a threshold voltage when a source voltage and the back gate voltage of the transistor are 0 (V), CG1 is a capacitance per unit area of the gate insulator, and CG2 is a capacitance per unit area of the back gate insulator.

Due to the back gate effect described above, the voltage for fully depleting the first semiconductor 3 fluctuates in the variable channel resistance circuit of the first embodiment. When the back gate voltage is higher than the source voltage, the voltage required for full depletion decreases as compared to when the back gate voltage is equal to the source voltage. When the back gate voltage is lower than the source voltage, on the other hand, the voltage required for full depletion increases as compared to when the back gate voltage is equal to the source voltage.

In the variable channel resistance circuit of the first embodiment, the back gate electrode for the first semiconductor 3 corresponds to the second semiconductor 5. The voltage of the second semiconductor 5 is a voltage between the voltage VD applied to the third electrode 7 and the voltage VS applied to the fourth electrode 8. When the voltages at the first electrode 1 and the second electrode 6 are V2 and VD≦V2, full depletion can be attained even with higher voltage because of the back gate effect. Therefore, if the voltage at the first electrode 1 is V2, the first semiconductor 3 can be fully depleted and enters the insulating state. When VD>V2, on the other hand, lower voltage is necessary for full depletion. Accordingly, if the voltage at the first electrode 1 is V2, the first semiconductor 3 enters the conductive state in some cases. The resistance RCH of the channel region of the second semiconductor 5 in this case is expressed by Expression (6c), not Expression (6b).

In the case where the voltage for fully depleting the first semiconductor 3 is lowered because of high carrier density of the first semiconductor 3 or other factors, even when both the voltages at the first electrode 1 and the second electrode 6 are V1, the first semiconductor 3 cannot be fully depleted in some cases. The resistance RCH of the channel region of the second semiconductor 5 in this case is changed from that of Expression (6a) and expressed as follows.

1/RCH=μ·(W/L)·C2·(V1−VS−VTH2) Expression (6a′)

As described above, the variable channel resistance circuit of the first embodiment is capable of selecting the channel resistance with higher degree of freedom through the change of the voltage for full depletion or the adjustment of the values of VD and VS. Taking the back gate effect into account, full depletion of the n-type first semiconductor 3 is realized by setting a minimum value of the voltage applied to the second electrode 6 to be equal to or smaller than a minimum value of the voltages applied to the plurality of electrodes that are connected to the second semiconductor 5.

In addition, the same circuit can also be obtained when the first semiconductor 3 is a p-type semiconductor having a bandgap of 2 (eV) or greater. However, the relation of the voltage magnitude is reversed to that when the first semiconductor 3 is an n-type semiconductor. That is, the p-type first semiconductor 3 is fully depleted and enters the insulating state when the voltage applied to the first electrode 1 is equal to or higher than the voltage applied to the second electrode 6. When the voltage applied to the first electrode 1 is equal to or lower than the voltage applied to the second electrode 6, on the other hand, the p-type first semiconductor 3 enters an accumulation state. The full depletion of the p-type first semiconductor 3 is realized by setting a maximum value in the range of the voltage applied to the first electrode 1 to be equal to or larger than a maximum value in the range of the voltage applied to the second electrode 6. Further, taking the back gate effect into account, the full depletion of the p-type first semiconductor 3 is realized by setting a maximum value of the voltage applied to the second electrode 6 to be equal to or larger than a maximum value of the voltages applied to the plurality of electrodes that are connected to the second semiconductor 5. The effect of the present invention is obtained also by setting the maximum value of the voltage applied to the second electrode 6 to be equal to or smaller than a minimum value of the voltages applied to the plurality of electrodes that are connected to the second semiconductor 5.

Note that, in FIG. 4, two (three-terminal) transistors 19 are transistors that are necessary in the circuit configuration in the case of realizing the operation of the variable channel resistance element of the present invention with the use of conventional normal (three-terminal) transistors.

### Second Embodiment

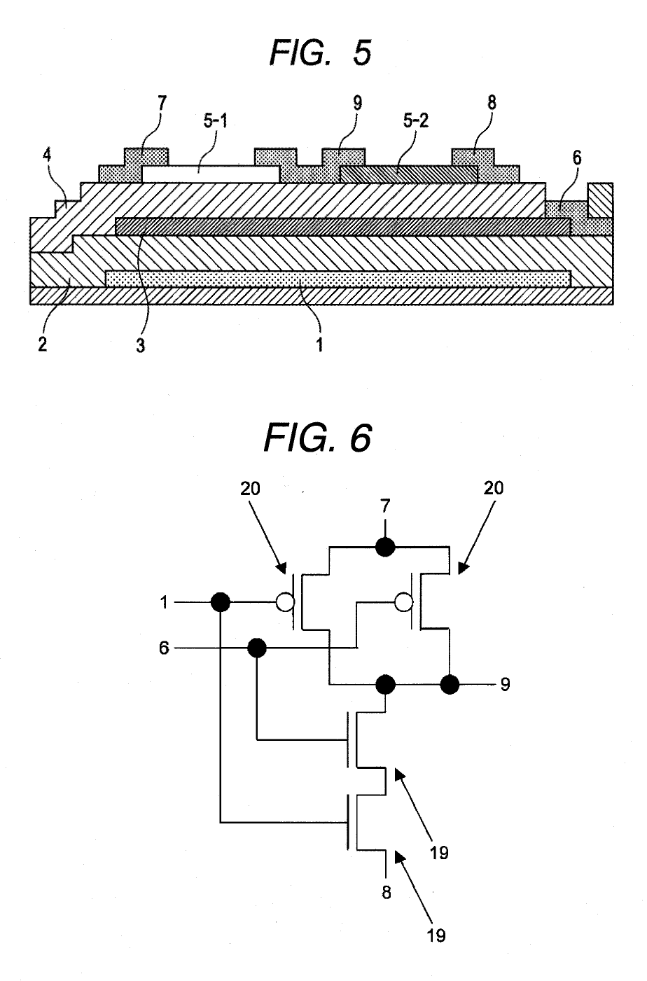

A second embodiment of the present invention is an example in which the semiconductor device of the present invention is used for a NAND circuit. FIG. 5 is a cross-sectional view of the NAND circuit of the second embodiment.

The NAND circuit of the second embodiment has the structure in which a first electrode 1, a first insulator 2, a first semiconductor 3 which is an n-type semiconductor having a bandgap of 2 eV or greater, a second insulator 4, a second semiconductor (p-type) 5-1, and a second semiconductor (n-type) 5-2 are stacked on a substrate. The NAND circuit further includes a second electrode 6 that is connected to the first semiconductor 3, a third electrode 7 that is connected to the second semiconductor (p-type) 5-1, and a fourth electrode 8 that is connected to the second semiconductor (n-type) 5-2. The NAND circuit further includes a fifth electrode 9 that is connected to both the second semiconductor (p-type) 5-1 and the second semiconductor (n-type) 5-2. The n-type first semiconductor 3 is fully depleted to enter an insulating state when a voltage applied to the first electrode 1 is equal to or lower than a voltage applied to the second electrode 6. When the voltage applied to the first electrode 1 is equal to or higher than the voltage applied to the second electrode 6, on the other hand, the n-type first semiconductor 3 enters an accumulation state. The full depletion of the n-type first semiconductor 3 is realized by setting a minimum value in the range of the voltage applied to the first electrode 1 to be equal to or smaller than a minimum value in the range of the voltage applied to the second electrode 6. In the second embodiment, the maximum value and the minimum value of each of the voltages applied to the first electrode 1 and the second electrode 6 are represented by V1 and V2, respectively, the voltage applied to the third electrode 7 is represented by VDD, and the voltage applied to the fourth electrode 8 is represented by VSS. VDD is higher than VSS, V1 is equal to or higher than VDD, and V2 is equal to or lower than VSS. Further, taking the back gate effect into account, the full depletion of the n-type first semiconductor 3 is realized by setting a minimum value of the voltage applied to the second electrode 6 to be equal to or smaller than a minimum value of the voltages applied to the plurality of electrodes that are connected to the second semiconductor (p-type) 5-1 and the second semiconductor (n-type) 5-2.

(1) When both the voltages at the first electrode 1 and the second electrode 6 are V1, the first semiconductor 3 is fully depleted and enters the insulating state. On this occasion, in a transistor that uses the second semiconductor (p-type) 5-1 as a channel and a transistor that uses the second semiconductor (n-type) 5-2 as a channel, the first electrode 1 functions as a gate, and a stacked film of three layers of the first insulator 2, the first semiconductor 3, and the second insulator 4 functions as a gate insulator. When capacitances per unit area of the first insulator 2, the first semiconductor 3, and the second insulator 4 are represented by C1, CS1, and C2, respectively, a capacitance C per unit area as the stacked gate insulator is expressed by Expression (4). The second semiconductor (p-type) 5-1 is turned OFF because the voltage at the first electrode 1 is V1 and the voltage at the third electrode 7 corresponding to a source is VDD. The second semiconductor (n-type) 5-2 is turned ON because the voltage at the first electrode 1 is V1 and the voltage at the fourth electrode 8 corresponding to a source is VSS. Therefore, the voltage at the fifth electrode 9 is VSS.

The voltages of the second semiconductor (p-type) 5-1 and the second semiconductor (n-type) 5-2 are equal to or lower than VDD, and accordingly equal to the voltage at the second electrode 6 or lower than the voltage at the second electrode 6. Owing to the back gate effect, even when the voltage at the first electrode 1 is equal to the voltage at the second electrode 6 or higher than the voltage at the second electrode 6, the first semiconductor 3 which is an n-type semiconductor can be fully depleted, and the insulating state of the first semiconductor 3 is thus maintained.

(2) When the voltage at the first electrode 1 is V1 and the voltage at the second electrode 6 is V2, the first semiconductor 3 enters the conductive state. On this occasion, in the transistor that uses the second semiconductor (p-type) 5-1 as a channel and the transistor that uses the second semiconductor (n-type) 5-2 as a channel, the first semiconductor 3 functions as a gate and the second insulator 4 functions as a gate insulator. The second semiconductor (p-type) 5-1 is turned ON because the voltage at the first semiconductor 3 is V2 and the voltage at the third electrode 7 corresponding to the source is VDD. The second semiconductor (n-type) 5-2 is turned OFF because the voltage at the first semiconductor 3 is V2 and the voltage at the fourth electrode 8 corresponding to the source is VSS. Therefore, the voltage at the fifth electrode 9 is VDD.

The voltages of the second semiconductor (p-type) 5-1 and the second semiconductor (n-type) 5-2 are equal to or higher than VSS, and accordingly equal to the voltage V2 at the second electrode 6 or higher than the voltage V2 at the second electrode 6. Owing to the back gate effect, the voltage at the first electrode 1 for fully depleting the first semiconductor 3 which is an n-type semiconductor is equal to the voltage at the second electrode 6 or lower than the voltage at the second electrode 6, and the conductive state of the first semiconductor 3 is thus maintained.

(3) When the voltage at the first electrode 1 is V2 and the voltage at the second electrode 6 is V1, the first semiconductor 3 is fully depleted and enters the insulating state. On this occasion, in the transistor that uses the second semiconductor (p-type) 5-1 as a channel and the transistor that uses the second semiconductor (n-type) 5-2 as a channel, the first electrode 1 functions as a gate, and a stacked film of three layers of the first insulator 2, the first semiconductor 3, and the second insulator 4 functions as a gate insulator. The second semiconductor (p-type) 5-1 is turned ON because the voltage at the first electrode 1 is V2 and the voltage at the third electrode 7 corresponding to the source is VDD. The second semiconductor (n-type) 5-2 is turned OFF because the voltage at the first electrode 1 is V2 and the voltage at the fourth electrode 8 corresponding to the source is VSS. Therefore, the voltage at the fifth electrode 9 is VDD.

The voltages of the second semiconductor (p-type) 5-1 and the second semiconductor (n-type) 5-2 are equal to or lower than VDD, and accordingly equal to the voltage V1 at the second electrode 6 or lower than the voltage V1 at the second electrode 6. Owing to the back gate effect, even when the voltage at the first electrode 1 is equal to the voltage at the second electrode 6 or higher than the voltage at the second electrode 6, the first semiconductor 3 which is an n-type semiconductor can be fully depleted, and the insulating state of the first semiconductor 3 is thus maintained.

(4) When the voltage at the first electrode 1 is V2 and the voltage at the second electrode 6 is V2, the first semiconductor 3 is fully depleted and enters the insulating state. On this occasion, in the transistor that uses the second semiconductor (p-type) 5-1 as a channel and the transistor that uses the second semiconductor (n-type) 5-2 as a channel, the first electrode 1 functions as a gate, a stacked film of three layers of the first insulator 2, the first semiconductor 3, and the second insulator 4 functions as a gate insulator. The second semiconductor (p-type) 5-1 is turned ON because the voltage at the first electrode 1 is V2 and the voltage at the third electrode 7 corresponding to the source is VDD. The second semiconductor (n-type) 5-2 is turned OFF because the voltage at the first electrode 1 is V2 and the voltage at the fourth electrode 8 corresponding to the source is VSS. Therefore, the voltage at the fifth electrode 9 is VDD.

The voltages of the second semiconductor (p-type) 5-1 and the second semiconductor (n-type) 5-2 are equal to or higher than VSS, and accordingly equal to the voltage V2 at the second electrode 6 or higher than the voltage V2 at the second electrode 6. Owing to the back gate effect, the voltage at the first electrode 1 required for fully depleting the first semiconductor 3 becomes equal to the voltage at the second electrode 6 or lower than the voltage at the second electrode 6. Accordingly, the insulating state of the first semiconductor 3, which is an n-type semiconductor, may be broken down. Even if the insulation is broken down, however, because the voltage at the second electrode 6 is V2, the second semiconductor (p-type) 5-1 is maintained to be ON while the second semiconductor (n-type) 5-2 is maintained to be OFF.

Table 1 summarizes the operations described above. VSC2 in Table 1 is the voltages of the second semiconductor (p-type) 5-1 and the second semiconductor (n-type) 5-2.

TABLE 1

| | | | | | Depletion | |
|---|---|---|---|---|---|---|
| | | | | | Condition of | |
| | Voltage at | Voltage at | Voltage at | Voltage of | Voltage at | State of |
| | First | Second | Fifth | Second | First | First |
| Case | Electrode | Electrode | Electrode | Semiconductor | Electrode | Semiconductor |
| (1) | V1 | V1 | VSS | ≦VDD | ≦V1 + VSC2 | Insulating |
| (2) | V1 | V2 | VDD | ≧VSS | ≦V2 − VSC2 | Conductive |
| (3) | V2 | V1 | VDD | ≦VDD | ≦V1 + VSC2 | Insulating |
| (4) | V2 | V2 | VDD | ≧VSS | ≦V2 − VSC2 | Insulating or |
| | | | | | | Conductive |

Through the operations in the above-mentioned cases (1) to (4), the circuit of the second embodiment realizes the NAND logic function. Realizing this function by a commonly-used transistor requires four transistors as illustrated in FIG. 6. On the other hand, the area required for the NAND circuit of the second embodiment is the one corresponding to two transistors. The NAND circuit of the second embodiment can therefore be reduced in circuit area in almost half as compared to a conventional one.

Note that, in FIG. 6, two n-channel transistors 19 and two p-channel transistors 20 are four transistors that are necessary in a commonly-used CMOS NAND circuit in the case of realizing the NAND logic operation of the element of the present invention with the use of conventional normal (three-terminal field-effect) transistors.

### Third Embodiment

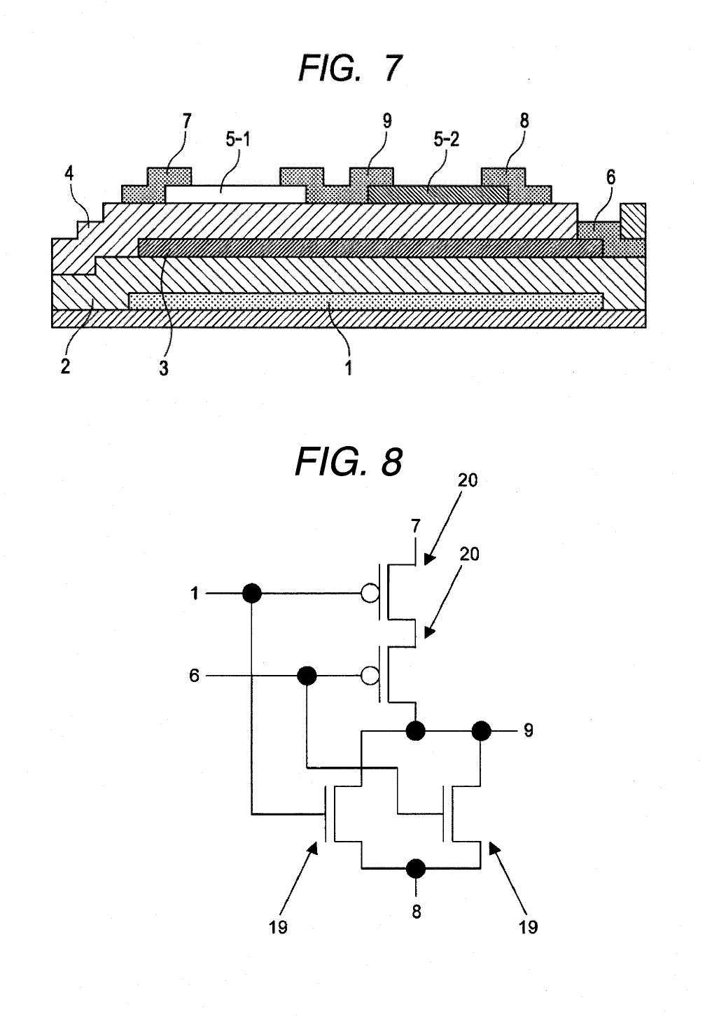

A third embodiment of the present invention is an example in which the semiconductor device of the present invention is used for a NOR circuit. FIG. 7 is a cross-sectional view of the NOR circuit of the third embodiment.

The NOR circuit of the third embodiment has the structure in which a first electrode 1, a first insulator 2, a first semiconductor 3 which is a p-type semiconductor having a bandgap of 2 eV or greater, a second insulator 4, a second semiconductor (p-type) 5-1, and a second semiconductor (n-type) 5-2 are stacked on a substrate. The NOR circuit further includes a second electrode 6 that is connected to the first semiconductor 3, a third electrode 7 that is connected to the second semiconductor (p-type) 5-1, and a fourth electrode 8 that is connected to the second semiconductor (n-type) 5-2. The NOR circuit further includes a fifth electrode 9 that is connected to both the second semiconductor (p-type) 5-1 and the second semiconductor (n-type) 5-2. The p-type first semiconductor 3 is fully depleted to enter an insulating state when a voltage applied to the first electrode 1 is equal to or higher than a voltage applied to the second electrode 6. When the voltage applied to the first electrode 1 is equal to or lower than the voltage applied to the second electrode 6, on the other hand, the p-type first semiconductor 3 enters an accumulation state. The full depletion of the p-type first semiconductor 3 is realized by setting a maximum value in the range of the voltage applied to the first electrode 1 to be equal to or higher than a maximum value in the range of the voltage applied to the second electrode 6. In the third embodiment, the maximum value and the minimum value of each of the voltages applied to the first electrode 1 and the second electrode 6 are represented by V1 and V2, respectively, the voltage applied to the third electrode 7 is represented by VDD, and the voltage applied to the fourth electrode 8 is represented by VSS. VDD is higher than VSS, V1 is equal to or higher than VDD, and V2 is equal to or lower than VSS. Further, taking the back gate effect into account, the full depletion of the p-type first semiconductor 3 is realized by setting a maximum value of the voltage applied to the second electrode 6 to be equal to or higher than a maximum value of the voltages applied to the plurality of electrodes that are connected to the second semiconductor (p-type) 5-1 and the second semiconductor (n-type) 5-2.

(1) When both the voltages at the first electrode 1 and the second electrode 6 are V1, the first semiconductor 3 is fully depleted and enters the insulating state. On this occasion, in a transistor that uses the second semiconductor (p-type) 5-1 as a channel and a transistor that uses the second semiconductor (n-type) 5-2 as a channel, the first electrode 1 functions as a gate, and a stacked film of three layers of the first insulator 2, the first semiconductor 3, and the second insulator 4 functions as a gate insulator. When capacitances per unit area of the first insulator 2, the first semiconductor 3, and the second insulator 4 are represented by C1, CS1, and C2, respectively, a capacitance C per unit area as the stacked gate insulator is expressed by Expression (4). The second semiconductor (p-type) 5-1 is turned OFF because the voltage at the first electrode 1 is V1 and the voltage at the third electrode 7 corresponding to a source is VDD. The second semiconductor (n-type) 5-2 is turned ON because the voltage at the first electrode 1 is V1 and the voltage at the fourth electrode 8 corresponding to a source is VSS. Therefore, the voltage at the fifth electrode 9 is VSS.

The voltages of the second semiconductor (p-type) 5-1 and the second semiconductor (n-type) 5-2 are equal to or lower than VDD, and accordingly equal to the voltage at the second electrode 6 or lower than the voltage at the second electrode 6. Owing to the back gate effect, the voltage at the first electrode 1 required for fully depleting the first semiconductor 3 becomes equal to the voltage at the second electrode 6 or higher than the voltage at the second electrode 6. Accordingly, the insulating state of the first semiconductor 3, which is a p-type semiconductor, may be broken down. Even if the insulation is broken down, however, because the voltage at the second electrode 6 is V1, the second semiconductor (p-type) 5-1 is maintained to be OFF while the second semiconductor (n-type) 5-2 is maintained to be ON.

(2) When the voltage at the first electrode 1 is V1 and the voltage at the second electrode 6 is V2, the first semiconductor 3 is fully depleted and enters the insulating state. On this occasion, in a transistor that uses the second semiconductor (p-type) 5-1 as a channel and a transistor that uses the second semiconductor (n-type) 5-2 as a channel, the first electrode 1 functions as a gate, and a stacked film of three layers of the first insulator 2, the first semiconductor 3, and the second insulator 4 functions as a gate insulator. The second semiconductor (p-type) 5-1 is turned OFF because the voltage at the first electrode 1 is V1 and the voltage at the third electrode 7 corresponding to the source is VDD. The second semiconductor (n-type) 5-2 is turned ON because the voltage at the first electrode 1 is V1 and the voltage at the fourth electrode 8 corresponding to the source is VSS. Therefore, the voltage at the fifth electrode 9 is VSS.

The voltages of the second semiconductor (p-type) 5-1 and the second semiconductor (n-type) 5-2 are equal to or higher than VSS, and accordingly equal to the voltage V2 at the second electrode 6 or higher than the voltage V2 at the second electrode 6. Owing to the back gate effect, even when the voltage at the first electrode 1 is equal to the voltage at the second electrode 6 or lower than the voltage at the second electrode 6, the first semiconductor 3 which is a p-type semiconductor can be fully depleted, and the insulating state of the first semiconductor 3 is thus maintained.

(3) When the voltage at the first electrode 1 is V2 and the voltage at the second electrode 6 is V1, the first semiconductor 3 enters the conductive state. On this occasion, in the transistor that uses the second semiconductor (p-type) 5-1 as a channel and the transistor that uses the second semiconductor (n-type) 5-2 as a channel, the first semiconductor 3 functions as a gate and the second insulator 4 functions as a gate insulator. The second semiconductor (p-type) 5-1 is turned OFF because the voltage at the first semiconductor 3 is V1 and the voltage at the third electrode 7 corresponding to the source is VDD. The second semiconductor (n-type) 5-2 is turned ON because the voltage at the first semiconductor 3 is V1 and the voltage at the fourth electrode 8 corresponding to the source is VSS. Therefore, the voltage at the fifth electrode 9 is VSS.

The voltages of the second semiconductor (p-type) 5-1 and the second semiconductor (n-type) 5-2 are equal to or lower than VDD, and accordingly equal to the voltage V1 at the second electrode 6 or lower than the voltage V1 at the second electrode 6. Owing to the back gate effect, the voltage at the first electrode 1 required for fully depleting the first semiconductor 3 which is a p-type semiconductor is equal to the voltage at the second electrode 6 or higher than the voltage at the second electrode 6, and the conductive state of first semiconductor 3 is thus maintained.

(4) When the voltage at the first electrode 1 is V2 and the voltage at the second electrode 6 is V2, the first semiconductor 3 is fully depleted and enters the insulating state. On this occasion, in the transistor that uses the second semiconductor (p-type) 5-1 as a channel and the transistor that uses the second semiconductor (n-type) 5-2 as a channel, the first electrode 1 functions as a gate, and a stacked film of three layers of the first insulator 2, the first semiconductor 3, and the second insulator 4 functions as a gate insulator. The second semiconductor (p-type) 5-1 is turned ON because the voltage at the first electrode 1 is V2 and the voltage at the third electrode 7 corresponding to the source is VDD. The second semiconductor (n-type) 5-2 is turned OFF because the voltage at the first electrode 1 is V2 and the voltage at the fourth electrode 8 corresponding to the source is VSS. Therefore, the voltage at the fifth electrode 9 is VDD.

The voltages of the second semiconductor (p-type) 5-1 and the second semiconductor (n-type) 5-2 are equal to or higher than VSS, and accordingly equal to the voltage V2 at the second electrode 6 or higher than the voltage V2 at the second electrode 6. Owing to the back gate effect, even when the voltage at the first electrode 1 is equal to the voltage at the second electrode 6 or lower than the voltage at the second electrode 6, the first semiconductor 3 which is a p-type semiconductor is fully depleted, and the insulating state of the first semiconductor 3 is thus maintained.

Table 2 summarizes the operations described above. VSC2 in Table 2 is the voltages of the second semiconductor (p-type) 5-1 and the second semiconductor (n-type) 5-2.

TABLE 2

| | | | | | Depletion | |
|---|---|---|---|---|---|---|
| | | | | | Condition of | |
| | Voltage at | Voltage at | Voltage at | Voltage of | Voltage at | State of |
| | First | Second | Fifth | Second | First | First |
| Case | Electrode | Electrode | Electrode | Semiconductor | Electrode | Semiconductor |
| (1) | V1 | V1 | VSS | ≦VDD | ≧V1 + VSC2 | Insulating or |
| | | | | | | Conductive |
| (2) | V1 | V2 | VSS | ≧VSS | ≧V2 − VSC2 | Insulating |
| (3) | V2 | V1 | VSS | ≦VDD | ≧V1 + VSC2 | Conductive |
| (4) | V2 | V2 | VDD | ≧VSS | ≧V2 − VSC2 | Insulating |

Through the operations in the above-mentioned cases (1) to (4), the circuit of the third embodiment realizes the NOR logic function. Realizing this function by a commonly-used transistor requires four transistors as illustrated in FIG. 8. On the other hand, the area required for the NOR circuit of the third embodiment is the one corresponding to two transistors. The NOR circuit of the third embodiment can therefore be reduced in circuit area in almost half as compared to a conventional one.

### Fourth Embodiment

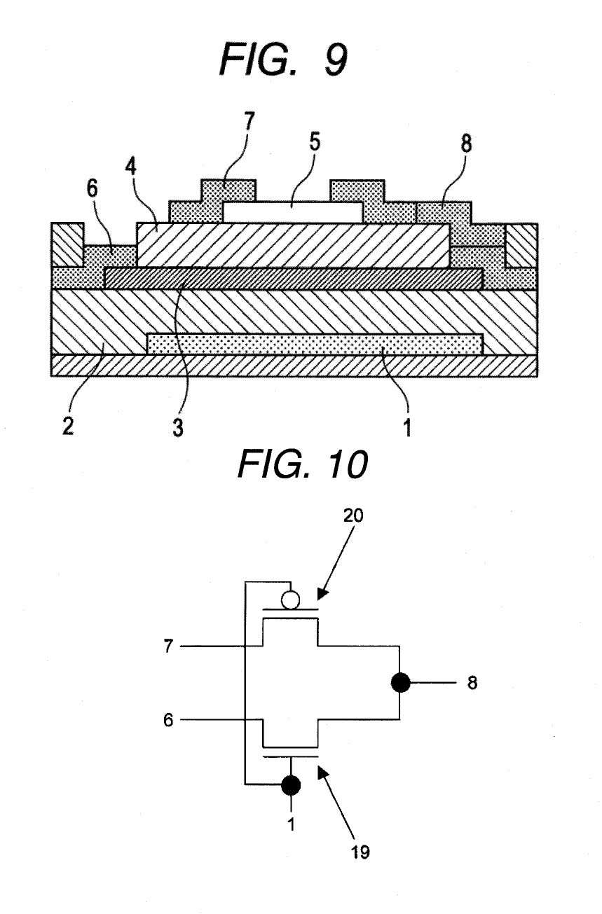

A fourth embodiment of the present invention is an example in which the semiconductor device of the present invention is used for a binary buffer circuit. FIG. 9 is a cross-sectional view of the binary buffer circuit of the fourth embodiment.

The binary buffer circuit of the fourth embodiment has the structure in which a first electrode 1, a first insulator 2, a first semiconductor 3 which is an n-type semiconductor having a bandgap of 2 eV or greater, a second insulator 4, and a second semiconductor 5 which is a p-type semiconductor, are stacked on a substrate. The binary buffer circuit further includes a second electrode 6 that is connected to the first semiconductor 3, a third electrode 7 that is connected to the second semiconductor 5, and a fourth electrode 8 that is electrically connected to both the first semiconductor 3 and the second semiconductor 5. The n-type first semiconductor 3 is fully depleted to enter an insulating state when a voltage applied to the first electrode 1 is equal to or lower than a voltage applied to the second electrode 6. When the voltage applied to the first electrode 1 is equal to or higher than the voltage applied to the second electrode 6, on the other hand, the n-type first semiconductor 3 enters an accumulation state. The full depletion of the n-type first semiconductor 3 is realized by setting a minimum value in the range of the voltage applied to the first electrode 1 to be equal to or smaller than a minimum value in the range of the voltage applied to the second electrode 6. In the fourth embodiment, the maximum value and the minimum value of each of the voltages applied to the first electrode 1 are represented by V1 and V2, respectively, the voltage applied to the second electrode 6 is represented by VD1, and the voltage applied to the third electrode 7 is represented by VD2. Note that, with regard to those voltages, V1>VD1>VD2>V2 is satisfied. Further, taking the back gate effect into account, the full depletion of the n-type first semiconductor 3 is realized by setting a minimum value of the voltage applied to the second electrode 6 to be equal to or smaller than a minimum value of the voltages applied to the plurality of electrodes that are connected to the second semiconductor 5.

(1) When the voltage at the first electrode 1 is V1, the first semiconductor 3 enters the conductive state. On this occasion, in the transistor that uses the second semiconductor 5 as a channel, the first semiconductor 3 functions as a gate and the second insulator 4 functions as a gate insulator. The second semiconductor 5 is turned OFF because the voltage at the first semiconductor 3 is VD1 and the voltage at the third electrode 7 corresponding to the source is VD2. Therefore, the voltage at the second electrode 6 is VD1.

The voltage at the second semiconductor 5 is lower than the voltage VD1 at the second electrode 6. Owing to the back gate effect, the voltage at the first electrode 1 required for fully depleting the first semiconductor 3, which is an n-type semiconductor, becomes equal to the voltage at the second electrode 6 or higher than the voltage at the second electrode 6. By setting the voltage at the first electrode 1 to be sufficiently higher than VD1, the insulating state of the first semiconductor 3 is maintained.

(2) When the voltage at the first electrode 1 is V2, the first semiconductor 3 is fully depleted and enters the insulating state. On this occasion, in the transistor that uses the second semiconductor 5 as a channel, the first electrode 1 functions as a gate, and a stacked film of three layers of the first insulator 2, the first semiconductor 3, and the second insulator 4 functions as a gate insulator. The second semiconductor 5 is turned ON because the voltage at the first electrode 1 is V2 and the voltage at the third electrode 7 corresponding to the source is VD2. Therefore, the voltage at the second electrode 6 is VD2.

The voltage at the second semiconductor 5 is lower than the voltage VD2 at the second electrode 6. Owing to the back gate effect, the voltage at the first electrode 1 required for fully depleting the first semiconductor 3, which is an n-type semiconductor, becomes equal to the voltage at the second electrode 6 or higher than the voltage at the second electrode 6. The insulating state of the first semiconductor 3 is thus maintained.

Through the operations in the above-mentioned cases (1) and (2), the circuit of the fourth embodiment realizes the binary buffer function. Realizing this circuit by a commonly-used transistor requires two transistors as illustrated in FIG. 10. On the other hand, the area required for the binary buffer circuit of the fourth embodiment is the one corresponding to one transistor. The binary buffer circuit of the fourth embodiment can therefore be reduced in circuit area in almost half as compared to a conventional one.

In this way, the functional circuits provided by the present invention can be mounted with about half the area of a conventional technology. Besides, the reduction of the mounting area leads to suppression of power consumption and cost.

In the above, the variable channel resistance circuit, the NAND circuit, the NOR circuit, and the binary buffer circuit have been exemplified as the functional circuits, but, as an application of the present invention, other functional circuits can be realized. For example, in the case where a switch is added in an analog circuit so that the operation of the analog circuit is switched by conductive/non-conductive states of the switch, the configuration of the present invention can be employed to reduce at least the area corresponding to the switch.

For convenience of description, the above-mentioned four embodiments are described by way of the unified three-dimensional structure in which the first electrode, the first insulator, the first semiconductor (wide gap (Eg≧2 eV) semiconductor), and the second semiconductor are stacked in this order from the substrate. The essence of the present invention resides only in the relative positional relation among those components, and hence the order of stacking with respect to the substrate may be reversed to that in the embodiments described above. In addition, there are no constraints on the second semiconductor in the embodiments of the present invention, and hence, in the case where both the p-type and the n-type are required in the second semiconductor as described above, it is possible to use a bipolar material such as crystalline Si that can easily produce different conductive types in different regions of the second semiconductor. The use of such material may facilitate the manufacture of the semiconductor device of the present invention. In Example 3 below, a specific example in which the stacking order of the components is reversed and the second semiconductor is bipolar monocrystalline Si is described.

Hereinafter, specific examples of the present invention are described. Note that, the present invention is not limited to the following examples.

### Example 1

Example 1 is a specific example of the variable channel resistance circuit described above with reference to FIG. 3.

In the variable channel resistance circuit of Example 1, a Mo film with a film thickness of 100 (nm) is used as the first electrode 1, a silicon dioxide (SiO₂) film with a film thickness of 150 (nm) is used as the first insulator 2, and a silicon dioxide (SiO₂) film with a film thickness of 50 (nm) is used as the second insulator 4. An a-IGZO film with a film thickness of 40 (nm) is used as the first semiconductor 3 that is an n-type semiconductor and the second semiconductor 5 that is an n-type semiconductor. Further, a Mo film with a film thickness of 100 (nm) is used as the second electrode 6 that is connected to the first semiconductor 3 and the third electrode 7 and the fourth electrode 8 that are connected to the second semiconductor 5. The films of those materials are deposited and formed by a method used in a conventional semiconductor device manufacturing process such as ordinary sputtering, CVD, or coating method, and are patterned by ordinary photolithography, etching, or printing method as well.

The variable channel resistance circuit of Example 1 is driven in a manner that a maximum value V1 of each of the voltages applied to the first electrode 1 and the second electrode 6 is set to 20 (V), a minimum value V2 thereof is set to 10 (V), a voltage VD applied to the third electrode 7 is set to 8.1 (V), and a voltage VS applied to the fourth electrode 8 is set to 8 (V). The resistance of a channel region of the second semiconductor is controlled by the field effect generated by the voltages applied to the first electrode and the second electrode.

The bandgap of a-IGZO is about 3 (eV), and the electron-hole pair generation rate is so low that no inversion layer is formed unless holes are injected. When the voltage applied to the first electrode 1 is equal to or lower than the voltage applied to the second electrode 6, the first semiconductor 3 made of the a-IGZO film is fully depleted and enters an insulating state. Therefore, the operating states of the variable channel resistance circuit of Example 1 are distinguished into the following four cases, depending on the voltages applied to the first electrode 1 and the second electrode 6.

(1) When both the voltages at the first electrode 1 and the second electrode 6 are V1=20 (V), the first semiconductor 3 is fully depleted and enters the insulating state. On this occasion, in a transistor that uses the second semiconductor 5 as a channel, the first electrode 1 functions as a gate, and a stacked film of three layers of the first insulator 2, the first semiconductor 3, and the second insulator 4 functions as a gate insulator. When capacitances per unit area of the first insulator 2, the first semiconductor 3, and the second insulator 4 are represented by C1, CS1, and C2, respectively, a capacitance C per unit area as the stacked gate insulator is determined as follows from Expression (4).

$$\begin{matrix}C = ( C 1 \cdot CS 1 \cdot C 2 ) / ( CS 1 \cdot C 2 + C 1 \cdot C 2 + C 1 \cdot CS 1 ) \\ = 1.65 \cdot {10}^{- 8} ( {Fcm}^{- 2} )\end{matrix} \qquad Expression ( {4}^{′} )$$

Using the capacitance C, the resistance RCH of the channel region of the second semiconductor is determined as follows from Expression (6a):

RCH=1/(μ·(W/L)·C·(V1−VS−VTH2))=276 (kΩ) Expression (6a′)

where μ=10 (cm²V⁻¹ sec⁻¹) is the mobility of the second semiconductor 5, W=20 (μm) and L=10 (μm) are respectively the channel width and the channel length of the transistor using the second semiconductor 5 as a channel, and VTH2=1 (V) is the threshold voltage of the transistor.

Owing to the back gate effect expressed by Expression (7), the full depletion of the first semiconductor 3 is realized even when the first electrode 1 has a voltage that is higher than the voltage V1 at the second electrode 6 by 18 (V). The insulating state of the first semiconductor 3 is thus maintained.

(2) When both the voltages at the first electrode 1 and the second electrode 6 are V2=10 (V), the first semiconductor 3 is fully depleted and enters the insulating state. The resistance RCH of the channel region of the second semiconductor 5 in this case is determined as follows from Expression (6b).

$$\begin{matrix}RCH = 1 / ( μ \cdot ( W / L ) \cdot C \cdot ( V 2 - VS - VTH 2 ) ) \\ = 3 , 037 ( k Ω )\end{matrix} \qquad Expression ( 6 {b}^{′} )$$

Owing to the back gate effect, the full depletion of the first semiconductor 3 is realized even when the first electrode 1 has a voltage that is higher than the voltage V2 at the second electrode 6 by 8 (V). The insulating state of the first semiconductor 3 is thus maintained.

(3) When the voltage at the first electrode 1 is V2=10 (V) and the voltage at the second electrode 6 is V1=20 (V), the first semiconductor 3 is fully depleted and enters the insulating state. The resistance RCH of the channel region of the second semiconductor in this case is also equal to that in Expression (6b′).

Owing to the back gate effect, if the voltage at the first electrode 1 is equal to or lower than a voltage determined by adding 8.1 (V) to the voltage at the second electrode 6, the first semiconductor 3 is fully depleted. In this operation, V2 is lower than V1 by 10 (V), and the insulating state of the first semiconductor 3 is thus maintained.

(4) When the voltage at the first electrode 1 is V1=20 (V) and the voltage at the second electrode 6 is V2=10 (V), the voltage of the first semiconductor 3 is V2. On this occasion, in the transistor that uses the second semiconductor 5 as a channel, the first semiconductor 3 functions as a gate and the second insulator 4 functions as a gate insulator. Using C2=6.91·10⁻⁸ (Fcm⁻²), the resistance RCH of the channel region of the second semiconductor in this case is determined as follows from Expression (6c).

$$\begin{matrix}RCH = 1 / ( μ \cdot ( W / L ) \cdot C 2 \cdot ( V 2 - VS - VTH 2 ) ) \\ = 724 ( k Ω )\end{matrix} \qquad Expression ( 6 {c}^{′} )$$

Owing to the back gate effect, if the voltage at the first electrode 1 is equal to or lower than a voltage determined by adding 8.1 (V) to the voltage at the second electrode 6, the first semiconductor 3 is fully depleted. V1 is higher than V2 by 10 (V), and the conductive state of the first semiconductor 3 is thus maintained.

As described above, Example 1 is the variable channel resistance circuit capable of changing the channel resistance to three different values in Expressions (6a′), (6b′), and (6c′) depending on the voltages applied to the respective electrodes.

Through the operations in the above-mentioned cases (1) to (4), Example 1 realizes the function of the variable channel resistance circuit whose area is halved, which is one embodiment of the present invention.

### Example 2

Example 2 is a specific example of the NAND circuit described above with reference to FIG. 5.

In the NAND circuit of Example 2, a Mo film with a film thickness of 100 (nm) is used as the first electrode 1 and a silicon dioxide (SiO₂) film with a film thickness of 100 (nm) is used as the first insulator 2 and the second insulator 4. An a-IGZO film with a film thickness of 40 (nm) is used as the first semiconductor 3 that is an n-type semiconductor and the second semiconductor (n-type) 5-2. Further, a pentacene film with a film thickness of 50 (nm) is used as the second semiconductor (p-type) 5-1. Further, a Mo film with a film thickness of 100 (nm) is used as the second electrode 6 that is connected to the first semiconductor 3 and the fourth electrode 8 that is connected to the second semiconductor (n-type) 5-2. An Ag film with a film thickness of 80 (nm) is used as the third electrode 7 that is connected to the second semiconductor (p-type) 5-1 and the fifth electrode 9 that is connected to both the second semiconductor (p-type) 5-1 and the second semiconductor (n-type) 5-2. The connections of the second electrode 6 to the fifth electrode 9 to the respective semiconductors are made so as to provide top contacts with respect to the first semiconductor 3 and the second semiconductor (n-type) 5-2 as illustrated in FIG. 5 and provide bottom contacts with respect to the second semiconductor (p-type) 5-1 unlike FIG. 5. In this case, however, the electrical connections are the same as those of FIG. 5. The Mo film, the SiO₂ film, and the a-IGZO film are deposited and formed by a method used in a conventional semiconductor device manufacturing process such as ordinary sputtering, CVD, or coating method, and are patterned by ordinary photolithography, etching, or printing method as well. The Ag film is formed and patterned by coating or printing method. The pentacene film is formed by vapor deposition or coating method.

The NAND circuit of Example 2 is driven in a manner that a maximum value V1 of each of the voltages applied to the first electrode 1 and the second electrode 6 is set to 20 (V), a minimum value V2 thereof is set to 0 (V), a voltage VDD applied to the third electrode 7 is set to 20 (V), and a voltage VSS applied to the fourth electrode 8 is set to 0 (V).

The bandgap of a-IGZO is about 3 (eV), and the electron-hole pair generation rate is so low that no inversion layer is formed unless holes are injected. When the voltage applied to the first electrode 1 is equal to or lower than the voltage applied to the second electrode 6, the first semiconductor 3 made of the a-IGZO film is fully depleted and enters an insulating state. Therefore, the operating states of the NAND circuit of Example 2 are distinguished into the following four cases, depending on the voltages applied to the first electrode 1 and the second electrode 6.

(1) When both the voltages at the first electrode 1 and the second electrode 6 are V1=20 (V), a-IGZO of the first semiconductor 3 is fully depleted and enters the insulating state. On this occasion, in a transistor that uses the second semiconductor (p-type) 5-1 as a channel and the transistor that uses the second semiconductor (n-type) 5-2 as a channel, the first electrode 1 functions as a gate, and a stacked film of three layers of the first insulator 2, the first semiconductor 3, and the second insulator 4 functions as a gate insulator. When capacitances per unit area of the first insulator 2, the first semiconductor 3, and the second insulator 4 are represented by C1, CS1, and C2, respectively, a capacitance C per unit area as the stacked gate insulator is determined as 1.65-10⁻⁸ (Fcm⁻²) from Expression (4). The second semiconductor (p-type) 5-1 is turned OFF because the voltage at the first electrode 1 is 20 (V) and the voltage at the third electrode 7 corresponding to a source is VDD=20 (V). The second semiconductor (n-type) 5-2 is turned ON because the voltage at the first electrode 1 is 20 (V) and the voltage at the fourth electrode 8 corresponding to a source is VSS=0 (V). Therefore, the voltage at the fifth electrode 9 is 0 (V).

The voltages of the second semiconductor (p-type) 5-1 and the second semiconductor (n-type) 5-2 are equal to or lower than 20 (V) and accordingly equal to the voltage V1=20 (V) at the second electrode 6 or lower than the voltage V1 at the second electrode 6. Owing to the back gate effect, even when the voltage at the first electrode 1 is equal to the voltage at the second electrode 6 or higher than the voltage at the second electrode 6, a-IGZO of the first semiconductor 3 can be fully depleted, and the insulating state of the first semiconductor 3 is thus maintained.

(2) When the voltage at the first electrode 1 is V1=20 (V) and the voltage at the second electrode 6 is V2=0 (V), the first semiconductor 3 enters the conductive state. On this occasion, in the transistor that uses the second semiconductor (p-type) 5-1 as a channel and the transistor that uses the second semiconductor (n-type) 5-2 as a channel, the first semiconductor 3 functions as a gate and the second insulator 4 functions as a gate insulator. The second semiconductor (p-type) 5-1 is turned ON because the voltage at the first semiconductor 3 is V2=0 (V) and the voltage at the third electrode 7 corresponding to the source is VDD=20 (V). The second semiconductor (n-type) 5-2 is turned OFF because the voltage at the first semiconductor 3 is V2=0 (V) and the voltage at the fourth electrode 8 corresponding to the source is VSS=0 (V). Therefore, the voltage at the fifth electrode 9 is 20 (V).

The voltages at the second semiconductor (p-type) 5-1 and the second semiconductor (n-type) 5-2 are equal to or higher than 0 (V) and accordingly equal to the voltage V2=0 (V) at the second electrode 6 or higher than the voltage V2 at the second electrode 6. Owing to the back gate effect, the voltage at the first electrode 1 required for fully depleting the first semiconductor 3 is equal to the voltage at the second electrode 6 or lower than the voltage at the second electrode 6, and the conductive state of the first semiconductor 3 is thus maintained when the voltage V1 of the first electrode is 20 (V).

(3) When the voltage at the first electrode 1 is V2=0 (V) and the voltage at the second electrode 6 is V1=20 (V), the first semiconductor 3 is fully depleted and enters the insulating state. On this occasion, in the transistor that uses the second semiconductor (p-type) 5-1 as a channel and the transistor that uses the second semiconductor (n-type) 5-2 as a channel, the first electrode 1 functions as a gate, and a stacked film of three layers of the first insulator 2, the first semiconductor 3, and the second insulator 4 functions as a gate insulator. The second semiconductor (p-type) 5-1 is turned ON because the voltage at the first electrode 1 is V2=0 (V) and the voltage at the third electrode 7 corresponding to the source is VDD=20 (V). The second semiconductor (n-type) 5-2 is turned OFF because the voltage at the first electrode 1 is V2=0 (V) and the voltage at the fourth electrode 8 corresponding to the source is VSS=0 (V). Therefore, the voltage at the fifth electrode 9 is 20 (V).

The voltages of the second semiconductor (p-type) 5-1 and the second semiconductor (n-type) 5-2 are equal to or lower than 20 (V) and accordingly equal to the voltage V1 at the second electrode 6 or lower than the voltage V1 at the second electrode 6. Owing to the back gate effect, even when the voltage at the first electrode 1 is equal to the voltage at the second electrode 6 or higher than the voltage at the second electrode 6, a-IGZO of the first semiconductor 3 can be fully depleted, and the insulating state of the first semiconductor 3 is thus maintained.

(4) When both the voltage at the first electrode 1 and the voltage at the second electrode 6 are V2=0 (V), the first semiconductor 3 is fully depleted and enters the insulating state. On this occasion, in the transistor that uses the second semiconductor (p-type) 5-1 as a channel and the transistor that uses the second semiconductor (n-type) 5-2 as a channel, the first electrode 1 functions as a gate, and a stacked film of three layers of the first insulator 2, the first semiconductor 3, and the second insulator 4 functions as a gate insulator. The second semiconductor (p-type) 5-1 is turned ON because the voltage at the first electrode 1 is V2=0 (V) and the voltage at the third electrode 7 corresponding to the source is VDD=20 (V). The second semiconductor (n-type) 5-2 is turned OFF because the voltage at the first electrode 1 is V=0 (V) and the voltage at the fourth electrode 8 corresponding to the source is VSS=0 (V). Therefore, the voltage at the fifth electrode 9 is 20 (V).

The voltages at the second semiconductor (p-type) 5-1 and the second semiconductor (n-type) 5-2 are equal to or higher than 0 (V) and accordingly equal to the voltage V2 at the second electrode 6 or higher than the voltage V2 at the second electrode 6. Owing to the back gate effect, the voltage at the first electrode 1 required for fully depleting the first semiconductor 3 is equal to the voltage at the second electrode 6 or lower than the voltage at the second electrode 6. Accordingly, the insulating state of the first semiconductor 3 may be broken down. Even if the insulation is broken down, however, because the voltage at the second electrode 6 is V2, the second semiconductor (p-type) 5-1 is maintained to be ON while the second semiconductor (n-type) 5-2 is maintained to be OFF.

Through the operations in the above-mentioned cases (1) to (4), Example 2 realizes the logic function of the NAND circuit whose area is halved, which is one embodiment of the present invention.

In addition, by replacing the first semiconductor 3 in Example 2 with the above-mentioned p-type wide gap (Eg≧2 eV) semiconductor, the logic function of the NOR circuit described in the third embodiment can be realized.

### Example 3

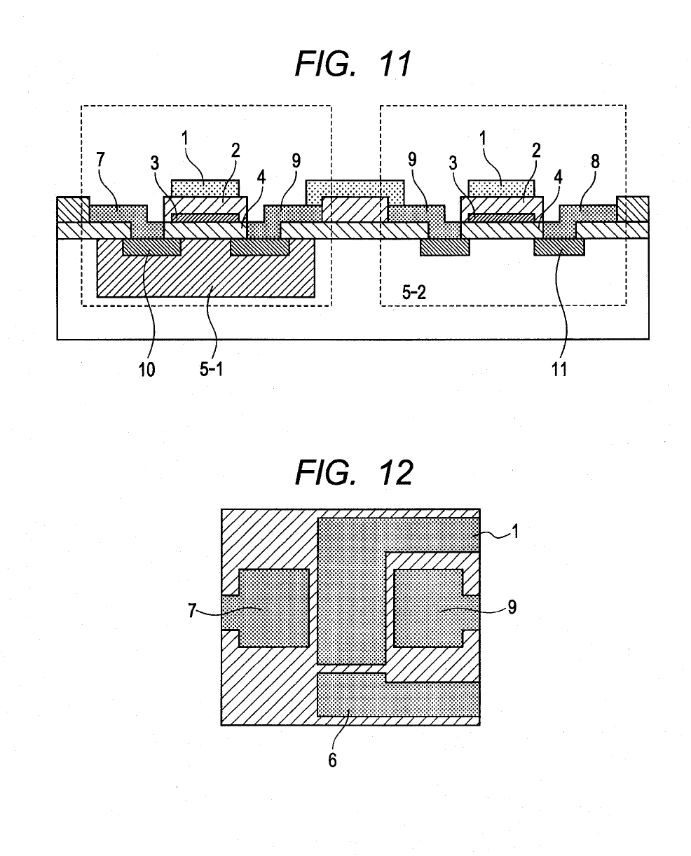

Example 3 is another specific example of the NAND circuit. FIG. 11 is a cross-sectional view of the NAND circuit. In Example 3, crystal Si is used as the second semiconductor, and the order of stacking the respective components with respect to the substrate is reversed compared to that in the second embodiment and Example 2.

The NAND circuit of Example 3 uses as a substrate a monocrystalline Si wafer that includes an N-well region 5-1 functioning as the second semiconductor (n-type) as part of a p-type substrate (P-sub region) 5-2 with low acceptor density functioning as the second semiconductor (p-type). The Si substrate further includes at least two n-type Si regions 11 with high donor density in the surface of the P-sub region 5-2 and at least two p-type Si regions 10 with high acceptor density in the surface of the N-well region 5-1. On the surface of the Si substrate, a silicon dioxide (SiO₂) film with a film thickness of 20 (nm) functioning as the second insulator 4 is provided. On the second insulator 4, a patterned In₂O₃ film with a film thickness of 5 (nm) functioning as the first semiconductor 3, a silicon oxynitride (SiON) film with a film thickness of 20 (nm) functioning as the first insulator 2, and a Cu film functioning as the first electrode 1 are provided in a stacked fashion. Opening portions are provided in the first insulator 2 and the second insulator 4 immediately above the p-type Si regions 10 and the n-type Si regions 11. Then, the third electrode 7, the fourth electrode 8, and the fifth electrode 9, each of which is made of a Cu film, are connected to the regions. The third electrode 7 is connected to one p-type Si region 10, the fourth electrode 8 is connected to one n-type Si region 11, and the fifth electrode 9 is connected to the remaining n-type Si region 11 and p-type Si region 10 together.

FIG. 12 illustrates planar arrangement of the respective electrodes in a plan view of the n-type Si region 10 of the N-well region 5-1 according to Example 3. The first semiconductor 3 made of the In₂O₃ film is connected to the second electrode 6 which is adjacent to the first electrode 1 functioning as a gate. The second electrode 6 is further wired to the adjacent P-sub region 5-2 and connected to the first semiconductor 3. A Cu film is used for the second electrode 6 similarly to the other electrodes. In the case where the resistance of the In₂O₃ film as the first semiconductor 3 is sufficiently low, the first semiconductors 3 in the two regions may be connected to each other by the In₂O₃ film itself. Although omitted in FIG. 12, the N-well region 5-1 and the P-sub region 5-2 in the monocrystalline Si substrate may be insulated from each other by a commonly-used device isolation method in an ordinary Si-LSI manufacturing process.

The NAND circuit of Example 3 is formed by an ordinary method used in a conventional semiconductor device manufacturing process. The N-well region 5-1, the n-type Si region 11, and the p-type Si region 10 in the monocrystalline Si substrate (P-sub region) 5-2 are formed by ion implantation of dopant impurities which is commonly-used in a Si-LSI manufacturing process. The second insulator 4 made of the SiO₂ film is formed by thermal oxidation of the monocrystalline Si substrate. The other members are deposited and formed by sputtering or CVD method, and then patterned by photolithography and etching method, which are ordinary methods as well.

Example 3 is an example in which the second semiconductor (p-type) 5-1 and the second semiconductor (n-type) 5-2 in the NAND circuit according to the second embodiment and Example 2 are embodied by using monocrystalline Si FETs. In other words, a Si-PMOS-FET of the N-well region 5-1 and a Si-NMOS-FET of the P-sub region 5-2 form the FET of the second semiconductor (p-type) 5-1 and the FET of the second semiconductor (n-type) 5-2, respectively. The operation is therefore the same as that of the NAND circuit according to the second embodiment and Example 2, and the same effect of reducing the area can be obtained. Note that, the film thickness of the insulator is small and a voltage value to be used is low. For example, the maximum value V1 and the minimum value V2 of the voltages applied to the first electrode 1 and the second electrode 6 are set to 2 (V) and 0 (V), respectively, and the voltage VDD applied to the third electrode 7 and the voltage VSS applied to the fourth electrode 8 are set to 2 (V) and 0 (V), respectively.

In this way, Example 3 can realize the logic function of the NAND circuit whose area is halved and which operates at higher speed and lower power consumption as compared to Example 2.

Although Example 3 has exemplified the use of a monocrystalline Si substrate, exactly the same NAND circuit can be constituted also by using a polycrystalline Si film on an insulating substrate or a silicon-on-insulator (SOI) substrate.

In addition, by replacing the first semiconductor 3 in

Example 3 with the above-mentioned p-type wide gap (Eg≧2 eV) semiconductor, the logic function of the NOR circuit described in the third embodiment can be realized.

### Example 4

Example 4 is a specific example of the binary buffer circuit described above with reference to FIG. 9.

In the binary buffer circuit of Example 4, a Mo film with a film thickness of 100 (nm) is used as the first electrode 1, and a silicon dioxide (SiO₂) film with a film thickness of 100 (nm) is used as the first insulator 2 and the second insulator 4. An a-IGZO film with a film thickness of 40 (nm) is used as the first semiconductor 3 which is an n-type semiconductor. A pentacene film with a film thickness of 40 (nm) is used as the second semiconductor 5 which is a p-type semiconductor. Further, a Mo film with a film thickness of 100 (nm) is used as the second electrode 6 that is connected to the first semiconductor 3, the third electrode 7 that is connected to the second semiconductor 5, and the fourth electrode 8 that is connected to the first semiconductor 3 and the second semiconductor 5 in common. The method of forming those components is the same as that described in Example 2.

The binary buffer circuit of Example 4 is driven in a manner that a maximum value V1 of the voltage applied to the first electrode 1 is set to 15 (V), a minimum value V2 thereof is set to 0 (V), a voltage VD1 applied to the second electrode 6 is set to 10 (V), and a voltage VD2 applied to the third electrode 7 is set to 5 (V).

The bandgap of a-IGZO is about 3 (eV), and the electron-hole pair generation rate is so low that no inversion layer is formed unless holes are injected. When the voltage applied to the first electrode 1 is equal to or lower than the voltage applied to the second electrode 6, the first semiconductor 3 made of the a-IGZO film is fully depleted and enters an insulating state. Therefore, the operating states of the binary buffer circuit of Example 4 are distinguished into the following two cases, depending on the voltages applied to the first electrode 1 and the second electrode 6.

(1) When the voltage at the first electrode 1 is V1=15 (V), the first semiconductor 3 enters the conductive state. On this occasion, in a transistor that uses the second semiconductor 5 as a channel, the first semiconductor 3 functions as a gate and the second insulator 4 functions as a gate insulator. The second semiconductor 5 is turned OFF because the voltage at the first semiconductor 3 is VD1 and the voltage at the third electrode 7 corresponding to a source is VD2. Therefore, the voltage at the fifth electrode 9 is 10 (V).

The voltage at the second semiconductor 5 is 5 (V) or higher and 10 (V) or lower and accordingly equal to the voltage VD1 at the second electrode 6 or lower than the voltage VD1 at the second electrode 6. Owing to the back gate effect, the voltage at the first electrode 1 required for fully depleting the first semiconductor 3 which is an n-type semiconductor is equal to the voltage at the second electrode 6 or higher than the voltage at the second electrode 6. The voltage at the first electrode 1 is 15 (V), which is sufficiently higher than VD1, and the conductive state of the first semiconductor 3 is thus maintained.

(2) When the voltage at the first electrode 1 is V2=0 (V), the first semiconductor 3 is fully depleted and enters an insulating state. On this occasion, in a transistor that uses the second semiconductor 5 as a channel, the first electrode 1 functions as a gate and a stacked film of three layers of the first insulator 2, the first semiconductor 3, and the second insulator 4 functions as a gate insulator. The second semiconductor 5, which is a p-type semiconductor, is turned ON because the voltage at the first electrode 1 is V2 and the voltage at the third electrode 7 corresponding to the source is VD2. Therefore, the voltage at the fifth electrode 9 is 5 (V).

The voltage at the second semiconductor 5 is 5 (V) or higher and 10 (V) or lower and accordingly equal to the voltage VD1 at the second electrode 6 or lower than the voltage VD1 at the second electrode 6. Owing to the back gate effect, the voltage at the first electrode 1 required for fully depleting the first semiconductor 3 which is an n-type semiconductor is equal to the voltage at the second electrode 6 or higher than the voltage at the second electrode 6. The conductive state of the first semiconductor 3 is thus maintained.

Through the operations in the above-mentioned cases (1) and (2), Example 4 realizes the function of the binary buffer circuit whose area is halved, which is one embodiment of the present invention.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-249443, filed Nov. 8, 2010, which is hereby incorporated by reference herein in its entirety.

1. A semiconductor device, comprising an electrode, a first insulator, a first semiconductor having a bandgap of 2 eV or greater, a second insulator, and a second semiconductor, which are stacked on one another, wherein:
the electrode is in contact with the first insulator;
the first semiconductor is sandwiched between the first insulator and the second insulator;
the second semiconductor is in contact with the second insulator; and
the semiconductor device at least further comprises one or more electrodes in contact with the first semiconductor and two or more electrodes in contact with the second semiconductor.

2. The semiconductor device according to claim 1, wherein a resistance of a channel region of the second semiconductor changes through application of a voltage to a first electrode, which is the electrode in contact with the first insulator, and a voltage to a second electrode, which is the one or more electrodes in contact with the first semiconductor.

3. The semiconductor device according to claim 2, wherein the first semiconductor comprises a metal-oxide semiconductor.

4. The semiconductor device according to claim 3, wherein the first semiconductor comprises a metal-oxide semiconductor containing In, Ga, and Zn as main constituent elements.

5. A method of driving a semiconductor device comprising an electrode, a first insulator, a first semiconductor having a bandgap of 2 eV or greater, a second insulator, and a second semiconductor, which are stacked on one another,
the electrode being in contact with the first insulator,
the first semiconductor being sandwiched between the first insulator and the second insulator,
the second semiconductor being in contact with the second insulator,
the semiconductor device at least further comprising one or more electrodes in contact with the first semiconductor and two or more electrodes in contact with the second semiconductor,
the method comprising applying a voltage to a first electrode, which is the electrode in contact with the first insulator, and a voltage to a second electrode, which is the one or more electrodes in contact with the first semiconductor, to thereby change a resistance of a channel region of the second semiconductor.

6. The method of driving a semiconductor device according to claim 5, further comprising, when the first semiconductor is an n-type semiconductor, setting a minimum value in a range of the voltage applied to the first electrode to be equal to or smaller than a minimum value in a range of the voltage applied to the second electrode.

7. The method of driving a semiconductor device according to claim 6, further comprising setting a minimum value of the voltage applied to the second electrode to be equal to or smaller than a minimum value of voltages applied to the two or more electrodes in contact with the second semiconductor.

8. The method of driving a semiconductor device according to claim 5, further comprising, when the first semiconductor is a p-type semiconductor, setting a maximum value in a range of the voltage applied to the first electrode to be equal to or larger than a maximum value in a range of the voltage applied to the second electrode.

9. The method of driving a semiconductor device according to claim 8, further comprising setting a maximum value of the voltage applied to the second electrode to be equal to or larger than a maximum value of voltages applied to the two or more electrodes in contact with the second semiconductor.

10. The method of driving a semiconductor device according to claim 5, further comprising, when the first semiconductor is an n-type semiconductor, setting a minimum value of the voltage applied to the second electrode to be equal to or larger than a maximum value of voltages applied to the two or more electrodes in contact with the second semiconductor.

11. The method of driving a semiconductor device according to claim 5, further comprising, when the first semiconductor is a p-type semiconductor, setting a maximum value of the voltage applied to the second electrode to be equal to or smaller than a minimum value of voltages applied to the two or more electrodes in contact with the second semiconductor.
